(19) United States
(12) Patent Application Publication
(10) Pub. No.: US 2008/0290337 A1
(43) Pub. Date: Nov. 27, 2008

(54) Ultrathin Dielectrics and the Application Thereof in Organic Field Effect Transistors

(75) Inventors: Marcus Halik, Erlangen (DE); Hagen Klauk, Stuttgart (DE); Ute Zschieschang, Stuttgart (DE); Guenter Schmid, Hemhofen (DE); Franz Effenberger, Stuttgart (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: QIMONDA AG, Muenchen (DE)

(21) Appl. No.: 11/568,791

(22) PCT Filed: Nov. 17, 2005
(86) PCT No.: PCT/DE05/00847

§ 371 Date: Nov. 29, 2007

(30) Foreign Application Priority Data
May 7, 2004 (DE) 102004022603.2

(51) Int. Cl. H01L 51/10; H01L 51/40

(52) U.S. Cl. 257/40; 438/99; 257/E51.006; 257/E21.411

(57) ABSTRACT

An organic field effect transistor, having a substrate, a source electrode, a drain electrode and a gate electrode and an organic semiconductor material is disclosed. Arranged between the gate electrode and the organic semiconductor material is a dielectric layer (gate dielectric) obtained from a self-assembled monolayer of an organic compound having an anchor group, a linker group, a head group, and an aliphatic orientating group, the anchor group, the linker group, the head group, and the aliphatic orientating group being combined with one another in the order stated.

### BACKGROUND

High-quality, extremely thin dielectric layers are of exceptional interest for a multiplicity of applications. In particular the realization of inexpensive electronics on large-area flexible substrates, operating with low supply voltages, requires the availability of such layers for constructing transistors, capacitors, etc.

Organic field effect transistors can be used diversely. By way of example, organic field effect transistors are suitable as pixel control elements in active matrix screens. Such screens are usually produced with field effect transistors based on amorphous or polycrystalline silicon layers. The temperatures of usually more than 250° C. that are necessary for the production of high-quality transistors based on amorphous or polycrystalline silicon layers require the use of rigid and fragile glass or quartz substrates. By virtue of the relatively low temperatures at which transistors based on organic semiconductors are produced, which are usually less than 200° C., organic transistors permit the production of active matrix screens using inexpensive, flexible, transparent, unbreakable polymer films having considerable advantages over glass or quartz substrates.

A further field of application for organic field effect transistors is in the production of very inexpensive integrated circuits such as are used for example for active labeling and identification of merchandise and goods. These transponders are usually produced using integrated circuits based on monocrystalline silicon, which leads to considerable costs in the construction and connection technology. The production of transponders on the basis of organic transistors would lead to huge cost reductions and could assist transponder technology en route to a worldwide breakthrough. In this case, for successful market introduction of products based on organic field effect transistors, it is necessary for the transistors to operate with the lowest possible supply voltages. Therefore, the supply voltages ought not to be higher than approximately 2 V to 5 V.

The construction of an organic field effect transistor in accordance with the prior art is illustrated schematically in FIG. 1. In this case, the minimum gate-source voltage required for the reliable modulation of the charge carrier density in the channel of the transistor is in a linear relationship with the thickness of the gate dielectric; the thicker the gate dielectric, the greater the required gate-source voltage. Therefore, it is necessary to develop gate dielectrics that are as thin as possible and also enable, besides sufficiently good electrical insulation, an optimum molecular orientation of the organic semiconductor layer and hence high charge carrier mobility in the semiconductor. What are outstandingly suitable for this purpose are those molecules which form an electrically insulating molecular self-assembled monolayer (SAM) on the gate electrode.

The German patent applications DE 103 28 810 and DE 103 28 811 describe the preparation and use of molecules, T-SAMs (“Top-Linked Self Assembled Mono Layers”), which serve as an insulator layer and may be used for example for organic field effect transistors. The molecular structures described therein are particularly suitable for forming monolayers on silicon substrates with a natural silicon oxide layer.

When other gate materials are utilized, for example aluminum and titanium, as is for constructing integrated circuits on glass or flexible polymer substrates, which, due to the formation of a natural oxide layer, are likewise suitable substrates for the formation of monolayers made from molecules of the compounds described in DE 103 28 810 and DE 103 28 811, organic field effect transistors having the T-SAM insulator layers described in the abovementioned patent applications in conjunction with pentacene, tetracene and oligothiophenes, exhibit poorer electrical properties than when silicon is utilized as gate material. DE 10 2004 009 600.7 also describes SAMs for use in field effect transistors.

### SUMMARY

One embodiment provided an organic field effect transistor, having a substrate, a source electrode, a drain electrode and a gate electrode and an organic semiconductor material. Arranged between the gate electrode and the organic semiconductor material is a dielectric layer (gate dielectric) obtained from a self-assembled monolayer of an organic compound having an anchor group, a linker group, a head group, and an aliphatic orientating group, the anchor group, the linker group, the head group, and the aliphatic orientating group being combined with one another in the order stated.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 illustrates the construction of a field effect transistor in accordance with the prior art;

FIG. 2a illustrates a compound in accordance with the prior art which has been used for forming self-assembled monolayers in field effect transistors;

FIG. 2b illustrates a schematic illustration of the compounds according to the invention which can be used for forming self-assembled monolayers in field effect transistors;

FIG. 3 illustrates voltage characteristic curves of the field effect transistor according to the invention.

FIG. 4 illustrates on-state characteristic curves of the field effect transistor according to the invention.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

One embodiment of the present invention provides new classes of compound which can serve as a monomolecular dielectric for use in field effect transistors based on organic semiconductors. A further embodiment of the invention is to provide organic field effect transistors having a dielectric layer with improved properties. A further embodiment of the invention is to propose materials which may serve for use in the production of field effect transistors.

One embodiment provides for a field effect transistor having a substrate, including a source electrode, a drain electrode and a gate electrode, and also having an organic semiconductor material, there being arranged on the gate electrode a dielectric layer (gate dielectric) formed from a self-assembled monolayer of a compound having an aliphatic orientating group, a head group, a linker group and an anchor group, the aliphatic orientating group, the head group, the linker group and the anchor group being combined with one another in the order stated.

The materials according to the invention solve the problem of the poorer electrical properties of organic field effect transistors having the construction metal gate/T-SAM/semiconductor/metal contacts or having the construction metal gate/T-SAM/metal contact/semiconductor by means of an altered molecular construction in comparison with the T-SAM molecules described (e.g., 18-phenoxyoctadecyltrichlorosilane having the formula C₆H₅O(CH₂)₁₈SiCl₃). The structure of T-SAM in accordance with the prior art is reproduced in FIG. 2a.

One important structural element of the T-SAM layers according to the invention is the aliphatic orientating group combined with the head group.

What are suitable as aliphatic orientating groups are in particular relatively short n-alkane chains of the general formula —(CH₂)n-, where n denotes an integer from 2 to 10. The chains are particularly suitable if n has an even number. The aliphatic orientating group may be substituted by divalent heteroatoms, such as e.g., O or S. The aliphatic orientating group is bonded to the head group either directly or via a bridge atom.

Head groups used may be all groups which are able on the one hand to determine the orientation of the molecule and on the other hand to contribute to a stabilization of the self-assembled layer by means of interactions, such as e.g., dipole-dipole, CT interactions, ΠΠ interactions, or by means of the van der Waals forces.

Appropriate head groups include, in principle, all aromatics or heteroaromatics which contribute to a stabilization of the layer by means of the formation of ΠΠ interactions with adjacent molecules of the self-assembled monolayers.

Particularly suitable head groups according to the invention are aromatics or heteroaromatics having one- and two-ring systems since the spatial extent thereof best fulfils the space requirement for a densely packed monolayer. The particularly suitable groups are e.g., phenyl, thiophene, furan, pyrrole, oxazole, thiazole, imidazole and pyridine. In this case, oligomers of such molecular structural units are also possible provided that they are bonded to one another as linearly as possible in order to ensure dense packing on the surface. The attachment to the corresponding linker group may be effected via a bridge atom such as e.g., O or S or directly, the synthetic accessibility determining the variant.

The linker groups comprise n-alkane chains of the general formula —(CH₂)m-, where m is between 2 and 26. An even number for m is particularly preferred. The n-alkyl chain may also be substituted by divalent heteroatoms such as e.g., O or S. Linear chains having the general formula [(—CH₂—CH₂—X)z], where X denotes O or S and z is a number between 2 and 10, are therefore possible as well. According to the invention, the alkane or poly(thio)ether chain may also contain unsaturated bonds or have substituents.

The anchor group may be varied depending on the electrode materials and is intended to be chosen such that an interaction takes place between the anchor group and the surface of the gate electrode. By way of example, the anchor group may have a radical which is selected from the group consisting of R—SiCl₃, R—SiCl₂-alkyl, R—SiCl(alkyl)₂, R—Si(OR¹)₃, R—Si(OR¹)₂alkyl, or R—SiOR¹(alkyl)₂, if the electrode includes Si, Al, Ti, TaN, TiN or WN, or has a layer made of abovementioned metals or alloys of the metals with a native oxide layer or an oxide layer produced in a targeted manner which is in contact with the anchor group.

If the electrode has a layer which contains the hydroxyl groups such as e.g., a structure Al—OₓOH or TiO—ₓOH which is in direct contact with the anchor group, the anchor group may also have radicals which are selected from the group consisting of specifically R—SiCl₃, R—SiCl₂-alkyl, R—SiCl(alkyl)₂, R—Si(OR¹)₃, R—Si(OR¹)₂alkyl, or R—SiOR¹(alkyl)₂.

If the electrode has a layer having Si—H groups which are in direct contact with the anchor group, the anchor group may be selected from the group consisting of e.g., R—CHO or R—CH═CH₂, which is bonded to the corresponding substrate under the action of light (hv).

If the electrode is formed from gold or has a layer made of gold which is in contact with the anchor group, the anchor group may be R—SH, R—SAc, R—S—S—R1 or R—SO₂H.

In the examples above, R denotes a linker group described above, and R1 denotes an alkyl group, which can also be substituted by heteroatoms, by way of example.

The thickness of the dielectric layer corresponds approximately to the length of the molecules according to the invention which form the self-assembled monolayer. In a one embodiment, the dielectric layer has a thickness of approximately 1 to approximately 10 nm, of approximately 2 to approximately 5 nm. Suitable materials for the gate electrode are, in principle, all materials which contain a layer facing the self-assembled monolayer and interact with the anchor groups of the compounds according to the invention.

The materials for the gate electrode are aluminum (Al), titanium (Ti), titanium nitride (TiN), tantalum (Ta), tantalum nitride (TaN), tungsten (W), titanium-tungsten (TiW), tantalum-tungsten (TaW), tungsten nitride (WN), tungsten carbonitride (WCN), iridium oxide (IrO), ruthenium oxide (RuO), strontium ruthenium oxide (SrRuO), or a combination of the layers and/or materials. If appropriate, the gate electrode additionally also has a layer made of silicon (Si), titanium nitride silicon (TiNSi), silicon oxynitride (SiON), silicon oxide (SiO), silicon carbide (SiC) or silicon carbonitride (SiCN).

The materials for the source and drain electrodes are not critical for the function of the component. All conductive metals, formulations thereof or polymers are suitable, in principle. The following materials are mentioned by way of example: gold (Au), silver (Ag), copper (Cu), titanium (Ti), titanium nitride (TiN), tantalum (Ta), tantalum nitride (TaN), tungsten (W), titanium-tungsten (TiW), tantalum-tungsten (TaW), tungsten nitride (WN), tungsten carbonitride (WCN), iridium oxide, ruthenium oxide, strontium ruthenium oxide, platinum, palladium, gallium arsenide, etc. The source and/or drain electrode may also additionally have a layer made of Si, TiNSi, SiON, SiO, SiC or SiCN. Examples of suitable polymeric contact materials are PEDOT:PSS (Baytron®) or polyaniline.

The semiconductor material based on an organic semiconductor is selected from the group of “small molecules” in one particular embodiment.

The term “small molecules” is to be understood to mean all organic semiconductor materials which are not polymers.

In one embodiment, the organic semiconductor is selected from the “small molecules” group consisting of pentacene, tetracene, oligothiophene, phthalocyanines and merocyanines.

It is therefore possible to use all organic semiconductor molecules for which the spatial orientation in the layer and the optimum arrangement thereof on the dielectric are of importance.

The supply voltage of a field effect transistor depends in particular on the thickness of the dielectric layer (gate dielectric) arranged on the gate electrode. Therefore, the field effect transistor according to the invention can be operated with a supply voltage of less than 5 volts and in particular of less than 3 volts, namely within the range of 1 to 3 volts.

The field effect transistors according to the invention are suitable in particular for use in the “low cost” area of electronics, and especially for organic field effect transistors with low supply voltages.

One embodiment of the invention provides a production method for producing field effect transistors.

In the method according to the invention, a substrate based on inorganic or organic materials is provided, on which a gate electrode is deposited. The gate electrode can then be contacted with the compound according to the invention, in order to obtain a self-assembled monolayer of the compound according to the invention that is arranged on the gate electrode. As described above, the surface of the gate electrode has properties such that the anchor groups of the compounds according to the invention interact with the surface of the gate electrode. A self-assembled monolayer of the compound according to the invention that is obtained in this way can then be subjected to further production processes. Therefore, the next process provided in the method according to the invention is the deposition and patterning of a source electrode and a drain electrode with the subsequent deposition of a semiconductor material.

In one embodiment of the invention, the organic compound may be contacted with the material of the gate electrode by dipping a substrate with the gate electrode arranged thereon into a solution having the organic compound according to the invention.

Suitable solvents are, in particular, polar, aprotic solvents such as, for example, toluene, tetrahydrofuran or cyclohexane.

The density of the self-assembled monolayer of the organic compound and the deposition duration can be influenced by the concentration of the solution of the organic compound into which the substrate is dipped. The concentration of the solution within the range of approximately 10⁻⁴ to 0.1 mol % of the organic compound is particularly suitable for producing dense layers. The SAMs are deposited by dipping the substrate (with the defined first electrode) into the prepared solution. After the substrate has been dipped into the solution of the organic compound, a rinsing process with pure process solvent may subsequently be effected. Afterward, the substrate may, if appropriate, be rinsed with a readily volatile solvent such as, for example, acetone or dichloromethane and finally be dried. The drying may be effected for example in a furnace or on a hot plate under protective gas.

The organic compound may also be contacted with the gate electrode by vapor deposition of the organic compound onto the gate electrode.

The organic compound may then be deposited in a closed reactor with heating. The interior of the reactor is evacuated after loading with the substrate with a defined gate electrode and is ventilated with inert gas such as, for example, argon or nitrogen in order to remove oxygen residues. Working pressure and working temperature are then established, which essentially depend on the organic radical. A pressure of approximately 10⁻⁶ to 400 mbar and a temperature of approximately 80 to 200° C. are particularly preferred. The ideal process conditions depend on the volatility of the organic compound. The coating times are generally between 3 min and 24 h, depending on process conditions.

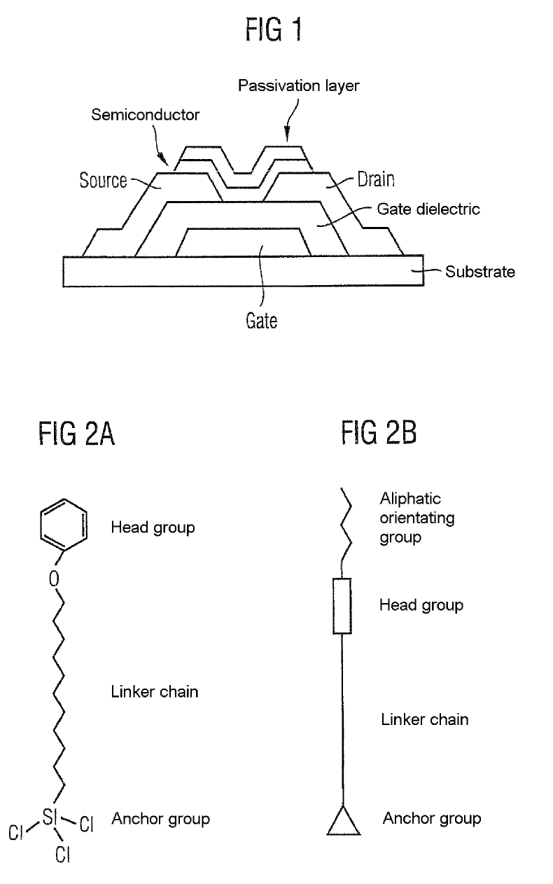

The construction of a field effect transistor illustrated in FIG. 1 has already been described in the introductory part.

Comparison of the compounds according to the invention (FIG. 2b) with the compounds in accordance with the prior art (FIG. 2a) reveals that the compounds according to the invention have an additional structural element, namely an aliphatic orientating group.

The mode of action of the aliphatic orientating group for the improvement of the electrical properties of organic field effect transistors can be described by analogy with the mode of action of octadecyltrichlorosilane (OTS) on SiO₂ surfaces. The mode of action is described e.g., in D. J. Gundlach et al., Organic Field Effect Transistors—Proceedings of SPIE, vol. 4466 (2001) 5464 and K. Klauk et al., J. Appl. Phys. 92 (2002) 5259 to 5263.

In this case, the presence of an aliphatic “surface” of the self-assembled monolayer appears to influence the growth of the organic semiconductors (pentacene, sexithiophene) in such a way that the resulting crystalline domains of the semiconductor are larger and have a higher degree of molecular order. This higher order in the layer construction generally results in an increase in the charge carrier mobility, a better sub-threshold slope and lower threshold voltages.

When applied to the materials according to the invention this means that the aliphatic orientating group performs the function of OTS on SiO₂, the insulation properties being critically determined by the remainder of the molecule, namely by the anchor groups, linker groups and head groups. Only one molecule has to be deposited for setting all these desired properties. The general construction of the materials according to the invention permits a high flexibility in the choice of the individual components for the synthesis thereof. As a result, the number of materials according to the invention is significantly extended in conjunction with improved function in comparison with the compounds described in the patent applications DE 103 28 810 and DE 103 28 81 1. The materials according to the invention are suitable in particular for the production of organic field effect transistors and integrated circuits based thereon with metallic gate electrodes. The introduction of the aliphatic orientating groups improves the electrical characteristics of the organic field effect transistor and enables complete integration of organic field effect transistors to form integrated circuits.

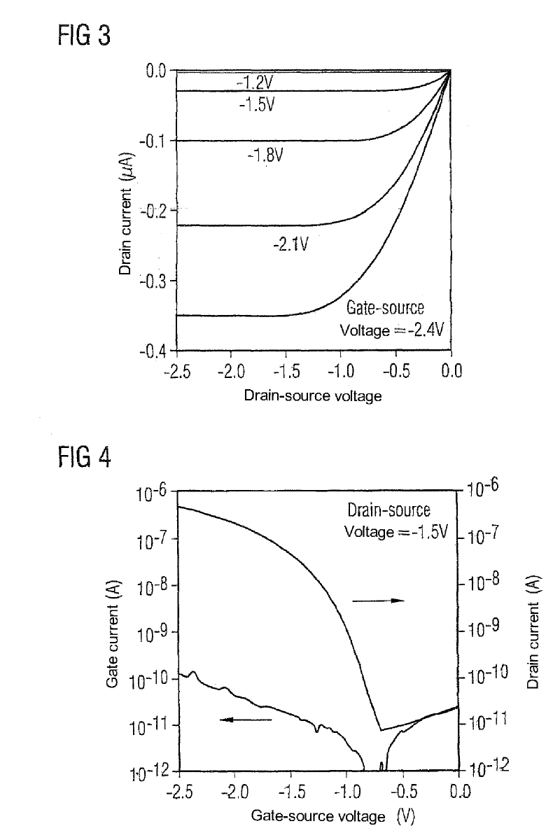

The electronic properties of the field effect transistor according to the invention are illustrated in FIG. 3 and FIG. 4. The organic field effect transistor was obtained by depositing 18-(4-hexylphenoxyoctadecyl)trichlorosilane on a silicon gate electrode. The self-assembled monolayer of the 18-(4-hexylphenoxyoctadecyl)trichlorosilane has a thickness of approximately 2.8 nm. The source and/or drain contacts are made of gold and the semiconductor material was pentacene.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1-29. (canceled)

30. An organic field effect transistor comprising;
a substrate;
a source electrode;
a drain electrode;
a gate electrode; and
an organic semiconductor material, there being arranged between the gate electrode and the organic semiconductor material a dielectric layer (gate dielectric) containing a self-assembled monolayer of an organic compound having an anchor group, a linker group, a head group, and an aliphatic orientating group, the anchor group, the linker group, the head group, and the aliphatic orientating group being combined with one another in the order stated.

31. The organic field effect transistor as claimed in claim 30, wherein the aliphatic orientating group is selected from a group comprising of short n-alkane chains of the general formula —(CH₂)n-, where n denotes an integer from 2 to 10.

32. The organic field effect transistor as claimed in claim 31, wherein n is an even number from 2 to 10.

33. The organic field effect transistor as claimed in claim 30, wherein the head group on the one hand determines the orientation of the molecule forming the self-assembled monolayer and on the other hand contributes to the stabilization of the self-assembled monolayer by means of interactions, such as dipole-dipole, CT interactions, ΠΠ interactions, or by means of the van der Waals forces.

34. The organic field effect transistor as claimed in claim 33, wherein the head group is selected from a group comprising of aromatics and heteroaromatics.

35. The organic field effect transistor as claimed in claim 34, wherein the head group is selected from a group comprising of phenyl, thiophene, furan, pyrrole, oxazole, thiazole, imidazole and pyridine.

36. The organic field effect transistor as claimed in claim 35, wherein the head group is an oligomer of the following monomers: phenyl, thiophene, furan, pyrrole, oxazole, thiazole, imidazole and pyridine.

37. The organic field effect transistor as claimed in claim 30, wherein the linker group is selected from a group comprising of n-alkane chains of the general formula —(CH₂)m-, where m denotes a number from 2 to 26.

38. The organic field effect transistor as claimed in claim 37, wherein m denotes an even number from 2 to 26.

39. The organic field effect transistor as claimed in claim 37, wherein the linker group contains at least one heteroatom selected from a group comprising of O and S.

40. The organic field effect transistor as claimed in claim 39, wherein the linker group corresponds to the formula [(—CH₂—CH₂—X)z], where X denotes O or S and z denotes an integer from 2 to 10.

41. The organic field effect transistor as claimed in claim 30, wherein the anchor group is selected from a group comprising of R—SiCl₃, R—SiCl₂-alkyl, R—SiCl(alkyl)₂, R—Si(OR¹)₃, R—Si(OR¹)₂alkyl, R—SiOR¹(alkyl)₂, R—CHO(hu), R—CH═CH₂(hu), R—SH, R—SAc, R—S—S—R1 or R—SO₂H.

42. The organic field effect transistor as claimed in claim 30, wherein the dielectric layer has a thickness of 2 to approximately 10 nm.

43. The organic field effect transistor as claimed in claim 30, wherein the gate electrode has a metal oxide layer at the surface.

44. The organic field effect transistor as claimed in claim 30, wherein the gate electrode is selected from a group comprising of aluminum, titanium, silicon, titanium nitride, tantalum, tantalum nitride, tungsten, titanium-tungsten, tantalum-tungsten, tungsten nitride, tungsten carbonitride, iridium oxide, ruthenium oxide, strontium ruthenium oxide, or from a combination of the abovementioned materials, and, if appropriate, a layer made of silicon, titanium nitride silicon, silicon oxynitride, silicon oxide, silicon carbide or silicon carbonitride is additionally provided.

45. The organic field effect transistor as claimed in claim 30, wherein the source and drain electrodes are selected, independently of one another, from a group comprising of gold, silver, copper, titanium, titanium nitride, tantalum, tantalum nitride, tungsten, titanium-tungsten, tantalum-tungsten, tungsten nitride, tungsten carbonitride, iridium oxide, ruthenium oxide, strontium ruthenium oxide, platinum, palladium, gallium arsenide, or from a combination of said materials, and, if appropriate, a layer made of silicon, titanium nitride silicon, silicon oxynitride, silicon oxide, silicon carbide or silicon carbonitride is additionally provided.

46. The organic field effect transistor as claimed in claim 30, wherein the organic semiconductor material is selected from the group of “small molecules”.

47. The organic field effect transistor as claimed in claim 46, wherein the semiconductor material is selected from a group comprising of pentacene, tetracene, oligothiophene, phthalocyanines and merocyanines.

48. The organic field effect transistor as claimed in claim 30, wherein it is operated with a supply voltage of less than 5 volts.

49. A method for producing an organic field effect transistor, comprising:
providing a substrate;
depositing a gate electrode;
contacting the gate electrode with a compound having an anchor group, a linker group, a head group, and an aliphatic orientating group, in order to obtain a monolayer of the organic compound that is self-assembled on the gate electrode;
depositing an organic semiconductor material; and
depositing and if necessary patterning a source electrode and a drain electrode.

50. A method for producing an organic field effect transistor, comprising:
providing a substrate;
depositing a gate electrode;
contacting the gate electrode with a compound having an anchor group, a linker group, a head group, and an aliphatic orientating group, in order to obtain a monolayer of the organic compound that is self-assembled on the gate electrode;
depositing and if necessary patterning a source electrode and a drain electrode; and
depositing an organic semiconductor material.

51. The method as claimed in claim 50, wherein the compound is present in a solvent when contacting the gate electrode with a compound.

52. The method as claimed in claim 51, wherein the solvent is an aprotic, polar solvent.

53. The method as claimed in claim 52, wherein the solvent is selected from a group consisting of toluene, tetrahydrofuran and cyclohexane.

54. The method as claimed in claim 50, wherein the concentration of the organic compound is present within the range of approximately 10⁻⁴ to approximately 0.1 mol %.

55. The method as claimed in claim 50, wherein the compound is vapor-deposited on the gate electrode when contacting the gate electrode with a compound.

56. The method as claimed in claim 55, wherein the pressure in the course of vapor-depositing the organic compound on the gate electrode lies within the range of approximately 10⁻⁶ to 400 mbar.

57. The method as claimed in claim 55, wherein the temperature in the course of vapor-depositing the organic compound onto the gate electrode lies within the range of approximately 80 to approximately 200° C.

58. The use of an organic compound as claimed in claim 30 in the production of an organic field effect transistor.

59. An organic field effect transistor comprising;
a substrate;
a source electrode;
a drain electrode;
a gate electrode; and
means for providing an organic semiconductor material, there being arranged between the gate electrode and the organic semiconductor material means a dielectric layer (gate dielectric) containing a self-assembled monolayer of an organic compound having an anchor group, a linker group, a head group, and an aliphatic orientating group, the anchor group, the linker group, the head group, and the aliphatic orientating group being combined with one another in the order stated.
